(19) United States
(12) Patent Application Publication
(10) Pub. No.: US 2014/0269007 A1
(43) Pub. Date: Sep. 18, 2014

(54) COMPLEMENTARY METAL OXIDE OR METAL NITRIDE HETEROJUNCTION MEMORY DEVICES WITH ASYMMETRIC HYSTERESIS PROPERTY

(71) Applicant: 4D-S, LTD., Perth, WA (US)

(72) Inventors: Lee Cleveland, Santa Clara, CA (US); Seshubabu Desu, Vestal, NY (US); Kurt Pfluger, Monte Sereno, CA (US); Jean Yang-Scharlotta, Glendale, CA (US); Theng Kiat (Peter) Tan, Cupertino, CA (US)

(21) Appl. No.: 14/214,478

(22) Filed: Mar. 14, 2014

Related U.S. Application Data
(60) Provisional application No. 61/786,601, filed on Mar. 15, 2013.

(51) Int. Cl. G11C 13/00; H01L 45/00

(52) U.S. Cl. CPC G11C 13/0021; H01L 45/145; H01L 45/1608
USPC 365/148; 257/2; 438/382

(57) ABSTRACT

A resistive memory device is disclosed. The resistive memory device comprises one or more metal oxide layers. The resistive memory device displays a property of asymmetric hysteresis loop formation when positive and negative electrical biases are applied across the device.

### CROSS-REFERENCES TO RELATED APPLICATIONS

This application is the non-provisional application of and claims the benefit under 35 USC §119(e) to U.S. Provisional Patent Application No. 61/786,601 filed on Mar. 15, 2013. This application is related to U.S. patent application Ser. No. 13/396,404 filed Feb. 14, 2012, which claims priority under 35 U.S.C. §371 to PCT Application No. PCT/US2010/045667, filed on Aug. 16, 2010, which in turn claims priority under 35 U.S.C. §119(e) to U.S. Provisional Application No. 61/234,183, filed on Aug. 14, 2009. This application is also related to U.S. Provisional Application No. 61/666,933 filed on Jul. 2, 2012. The disclosures of the above mentioned applications are all incorporated by reference herein in their entirety for all purposes.

### BACKGROUND

As Moore's Law has been predicted, the capacity of memory cells on silicon for the past 15-20 years has effectively doubled each year. Moore's Law roughly states that every year the amount of devices such as transistor gates or memory cells on a silicon wafer will double, thus doubling the capacity of the typical chip while the price will essentially stay the same. As the devices continue to shrink, device technology is starting to reach a barrier known as the quantum limit, that is, they are actually approaching atomic dimensions, so the cells cannot get any smaller.

Separately, disk drives have been a type of information storage which provided a significant portion peak capacity. The storage density provided by disk drives have been cheaper than semiconductor memory devices at least partially due to the way disk drives store and read individual bits of information in individual domains (magnetic transition sites) with an external probe. This method of storing and reading the information does not require individual circuit connections for each bit of storage location, thus requiring significantly less overhead than storage in semiconductor memory which does require the individual circuit connections. The individually connected semiconductor memory such as Flash memory, however, is preferable to disk drives in terms of resistance to shock as it has no moving parts which may be damaged by movement and shock.

As semiconductor device scaling passes 45 nanometer feature size, or node to 25 and 15 nanometer nodes, the semiconductor memory density are beginning to reach similar density and cost as disk drive storage. Multiple bit storage per device, where a multiple of data bits may be stored in a single cell by a division of ranges, has also been employed to increase density and reduce cost.

Semiconductor memories such as flash memory of the floating gate or charge trapping types suffer from other issues due to scaling. As the size of the devices become smaller, variations of a few electrons begin to manifest as large variations in device characteristics such as current, write speed, and erase speed. Such large variations further require increased write, read, and erase time to reach the same distribution ranges for operation and reduce the supportable dynamic ranges for multiple bit storage.

Yet one more concern for traditional flash type of semiconductor memory scaling is the reduction of the number of write/erase cycle the cell will tolerate before it permanently fails. Prior to the substantial reduction in cell size, the typical flash memory write/erase cycle tolerance rating is in the range of 1,000,000, however, as the feature size reduces in size, write/erase cycle tolerance rating has diminished to the range of 3,000 cycles. This reduction of write/erase cycle tolerance limits the applications for the memory. For example, for a memory device to also function in current SRAM and DRAM applications, such memory must tolerate data exchange at much higher repetition rates, typically several times per microsecond, resulting in 1,000,000 or more cycles.

Accordingly, what is desired are a memory device, system and method which overcome the above-identified problems. The memory device, system and method should be easily implemented, cost effective and adaptable to existing storage applications. The system and method should also be simple to integrate with other ICs in terms of processing and operating voltages. The present disclosure addresses such a need.

### SUMMARY

The present disclosure relates generally to memory devices and more particularly to memory devices that includes heterojunction metal oxide material and have asymmetric hysteresis property.

Some embodiments of the present invention disclose a memory device. The memory device comprises a first metal layer and a first metal oxide layer coupled to the first metal layer. The memory device may also includes a barrier layer coupled to the first metal oxide layer, a second metal oxide layer coupled to the barrier layer, and a second metal layer coupled to the second metal oxide layer. The memory device has a property of asymmetric hysteresis upon application electrical bias of opposite polarities.

The following detailed description, together with the accompanying drawings will provide a better understanding of the nature and advantages of the present invention.

### BRIEF DESCRIPTION OF THE DRAWINGS

FIG. 1 illustrates three types of memory devices in accordance with an embodiment of the present disclosure, FIGS. 6A and 6B illustrates two embodiments of such memory devices.

FIG. 2 illustrates the operation of a vacancy state conduction type of metal oxide device under positive and negative switching biases and the resulting IV shapes.

FIG. 3 illustrates the operation of an ionic state conduction type of metal oxide device under negative and positive switching biases and the resulting IV shapes.

FIG. 4 illustrates details of the operation of a vacancy state conduction type of metal oxide device.

FIG. 5 illustrates details of the operation of an ionic state conduction type of metal oxide device.

FIGS. 6A, 6B illustrates two embodiments of such memory device.

FIG. 6C shows experimental hysteresis loops for vacancy type and ionic type of memory devices according to embodiments of the present disclosure, where the metal oxide or metal nitride are selected and processed so that the hysteresis loops of the resulting device is asymmetric.

FIG. 6D is a graph illustrating an exemplary asymmetric hysteresis loop property of a memory device of the present disclosure.

FIGS. 7A-7D illustrate various steps in the fabrication of a memory device according to an embodiment of the present invention.

FIG. 8 illustrates a memory device structure according to another embodiment of the present invention.

FIG. 9 illustrates the operation of a switchable resistor that has a clockwise hysteresis of current versus voltage and a switchable resistor that has a counter clockwise hysteresis of current to voltage.

FIG. 10 is a diagram of a back to back switching resistor in accordance with an embodiment of the present invention.

FIG. 11 is a diagram of the operation a tri-state back-to-back switching resistor device according to an embodiment of the present invention.

FIG. 12 illustrates first method for addressing the tri-states of the back to back switching device of FIG. 11.

FIG. 13 is a diagram illustrating identifying the 00 state vs. 01, 10 states (nondestructive read) according to an embodiment of the present invention.

FIG. 14 is a diagram illustrating identifying a 10 state vs. 01 state (destructive read, need to reinstall the state after read) according to an embodiment of the present invention.

FIG. 15 illustrates addressing single cell of an array according to an embodiment of the present invention.

FIG. 16 illustrates creating asymmetry in the device to eliminate the need for resetting the device according to an embodiment of the present invention.

FIG. 17 is a diagram illustrating the energy levels in the metal oxide and the barrier layer's impact on the movement of oxygen ions according to an embodiment of the present invention.

### DETAILED DESCRIPTION OF SPECIFIC EMBODIMENTS

The present disclosure relates generally to memory devices, and more particularly to a memory device that includes a heterojunction which has a property of asymmetric hysteresis behavior described herein. The following description is provided to enable one of ordinary skill in the art to make and use the disclosed memory device. Various modifications to the preferred embodiments and the generic principles and features described herein will be readily apparent to those skilled in the art. Thus, the present disclosure is not intended to be limited to the embodiments shown, but is to be accorded the widest scope consistent with the principles and features described herein.

The present disclosure is directed to a memory device, methods of forming the device, and systems comprising the device. The memory device can be utilized in a variety of applications from a free standing nonvolatile memory to an embedded device in a variety of applications. These applications include but are not limited to embedded memory used in a wide range of SOC (system on chip) or system on package, switches in programmable or configurable ASIC, solid state drive used in computers and servers, memory used in mobile electronics like camera, cell phone, electronic pad, and build in memory in micro devices such as RF chips, mobile sensors and many others.

The memory device comprises a first metal layer and a first metal oxide layer coupled to the first metal layer. The memory device may include an optional barrier layer coupled to the first metal oxide layer. The memory device includes a second metal oxide layer coupled to the optional barrier layer or the first metal oxide layer. The memory device also includes a second metal layer coupled to the second metal oxide layer. These metal layers, optional barrier layers, and metal oxide layers can be of a variety of types and their use will be within the spirit and scope of the present disclosure.

More particularly, many of the embodiments disclosed herein will include PCMO as one of the metal oxide layers. It is well understood by one of ordinary skill in the art that the present disclosure should not be limited to this metal oxide layer, metal nitride layer, metal oxynitride layer or any other specific layer disclosed herein.

In many embodiments, the formation of the first metal oxide layer has a Gibbs free energy that is lower than the Gibbs free energy for the formation of the second metal oxide layer and there is a barrier layer of wider band gap material or higher oxygen diffusion constant than the first metal oxide, the second metal oxide, or both. The difference in the band gap or oxygen diffusion constant will form a barrier to impede oxygen ions or vacancies from moving between the first metal oxide and the second metal oxide.

This barrier can serve to improve the retention of a resistance memory state of the device even after the electric field is removed. The resistance memory state is typically formed by an externally applied electric field which drives the oxygen ions or vacancies from either the first metal oxide or the second metal oxide into the other metal oxide layer.

In some embodiments, the first metal oxide layer is described as a metal oxide layer comprising oxygen ions or vacancies. The first metal oxide layer may comprise one or more metal nitride layer or metal oxynitride layer comprising nitrogen and/or oxygen ions or vacancies. Similarly, although the second metal oxide layer is described as a metal oxide layer it also may comprise one or more metal nitride layer or a metal oxynitride layer in some embodiments.

Referring now to FIG. 1, shown herein are three type of metal oxide or metal nitride based devices, each device comprising at least a top electrode, a metal oxide or metal nitride or metal oxynitride layer of typically 10-1000 Angstrom thickness, and a bottom electrode. The device behavior is described herein with respect a metal oxide layer but is applicable to metal nitride or metal oxynitrides as well.

In the case where the metal oxide is stoichiometric, the metal oxide typically behaves as an insulator and will not conduct electron. When the metal oxide is very thin, on the order of a few to a few 10ths of Angstroms, direct tunneling and FN tunneling may occur.

If an oxygen deficient (sub-stoichiometric) metal oxide is present in the device as shown in the center device, the oxygen deficient oxide may contain vacancies that may form defect states in the middle of the band gap. When the mean distance of the oxygen vacancy is within the range of electron path length of the metal oxide, an oxygen vacancy based conduction path can be established by percolation which may allow electron conduction.

For the situation where an oxygen rich (super-stoichiometric) metal oxide is present, the excess oxygen ions can form defect states in the middle of the band gap as well. When the mean distance of the oxygen ion is within a percolation path distance threshold, an oxygen ion based conduction path can be established and allow electron conduction through the metal oxide layer.

Referring now to FIG. 2, under a positive switching bias condition when a positive bias is applied to the top electrode, oxygen vacancies can move toward the bottom electrode as illustrated in the left illustration of FIG. 2. This vacancy movement can disrupt the conduction path and result in a higher resistance state for the device.

When a negative bias is applied to the top electrode, the oxygen vacancies can be pulled toward the top electrode. This vacancy movement can establish or reestablish the conduction patch. It is noted that the bias field applied to the top electrode driving the vacancy movement will stop driving the vacancy movement once electron conduction begins. Thus, the process is self limiting as long as the applied bias does not exceed a breakdown voltage beyond which irreparable damage to the oxide bonds occur. This is also known as the break down limit. Finally, the hysteresis illustration at the right hand side of FIG. 2 shows that this vacancy conduction type of device tends to exhibit a clockwise IV loop at V>0 and a counter clockwise loop at V<0.

Referring now to FIG. 3, under a negative switching bias condition when a negative bias is applied to the top electrode, oxygen ions can move toward the bottom electrode as illustrated in the left illustration of FIG. 3. This ionic movement can disrupt the conduction path and result in a higher resistance state for the device.

When a positive bias is applied to the top electrode, the oxygen ions can be pulled toward the top electrode. This ionic movement can establish or reestablish the conduction patch. It is noted that the bias field applied to the top electrode driving the ionic movement will stop driving the ionic movement once electron conduction begins. Thus, the process is self limiting as long as the applied bias does not exceed a breakdown voltage beyond which irreparable damage to the oxide bonds occur. This is also known as the break down limit. Finally, the hysteresis illustration at the right hand side of FIG. 3 shows that this ionic conduction type of device tends to exhibit a counter-clockwise IV loop at V>0 and a clockwise loop at V<0.

Referring now to FIG. 4, shown herein is an embodiment of a vacancy type of metal oxide heterojunction memory device. The device comprises a top electrode, a top metal oxide which is oxygen deficient, a base metal oxide, and a bottom electrode. A heterojunction is formed by the interface of the top metal oxide and the base metal oxide. The base metal oxide may be thicker than the top metal oxide.

A low resistance state is shown where a first top resistance (R_{T1}) of the top metal oxide is similar in magnitude as a first base resistance (R_{B1}) of the base metal oxide. This low resistance state can also be known as the “1” state of the memory device. At the low resistance state, the top metal oxide is shown comprising oxygen vacancy and the base metal oxide is shown comprising oxygen ions.

A positive bias can be applied to the top electrode in a reset operation which may cause recombination of the oxygen vacancy from the top metal oxide and the oxygen ions from the base metal oxide to recombine at the heterojunction result in a depletion of oxygen vacancies in the top metal oxide as previously shown in FIG. 2 left illustration characterized by higher resistance. This reset operation may result in a high resistance state for the memory device where a second top resistance (R_{T2}) of the top metal oxide is greater than a second base resistance (R_{B2}) of the base metal oxide. The base metal oxide may also increase in resistance due to the recombination. By a selection of a base metal oxide layer that is significantly thicker, for example 5-200× thicker, than the top metal oxide, the base metal resistance will not be changed significantly by the recombination. This resulting high resistance state is dominated by the top metal oxide resistance and can be also known as the “0” state of the memory device.

A negative bias can be applied to the top electrode in a set operation which may cause the regeneration of the oxygen vacancies at the heterojunction to populate the top metal oxide and return the memory device to a low resistance state as is also shown in the middle illustration of FIG. 2. It is noted that the returned resistance state for each of the layers and the combination of the two oxide layers may not be exactly the same as the initial resistance states.

Referring now to FIG. 5, shown herein is an embodiment of an ionic type of metal oxide heterojunction memory device. The device comprises a top electrode, a top metal oxide which is oxygen-rich, a base metal oxide, and a bottom electrode. A heterojunction is formed by the interface of the top metal oxide and the base metal oxide. The base metal oxide may be thicker than the top metal oxide.

A low resistance state is shown where a first top resistance (R_{T1}) of the top metal oxide is similar in magnitude as a first base resistance (R_{B1}) of the base metal oxide. This low resistance state can also be known as the “1” state of the memory device. At the low resistance state, the top metal oxide is shown comprising oxygen ions and the base metal oxide is shown comprising oxygen vacancies.

A negative bias can be applied to the top electrode in a reset operation which may cause recombination of the oxygen ions from the top metal oxide and the oxygen vacancies from the base metal oxide to recombine at the heterojunction result in a depletion of oxygen ions in the top metal oxide as previously shown in FIG. 3 left illustration resulting in higher resistance. This reset operation may result in a high resistance state for the memory device where the second top resistance (R_{T2}) of the top metal oxide is greater than a second base resistance (R_{B2}) of the base metal oxide. The reasoning are similar to that previous described in [0047] for the vacancy type. The high resistance state can be also known as the “0” state of the memory device.

A positive bias can be applied to the top electrode in a set operation which may cause the regeneration of the oxygen ions at the heterojunction to populate the top metal oxide and return the memory device to a low resistance state as is previous shown by the middle illustration of FIG. 3.

FIG. 6A is an illustration of a memory device 10 which includes a bottom electrode 16, which in turn is coupled to a base metal oxide layer 14 which in turn is coupled to a top electrode 12 which is made of a metal. An optional barrier layer 20 (not shown) may be present between the base metal oxide layer 14 and the top electrode 12.

The top electrode 12 can be any metal, such as Platinum (Pt), Aluminum (Al), Ruthenium (Ru), Copper (Cu), Gold (Au), Tungsten (W), Titanium (Ti), Hafnium (Hf), Tantalum (Ta), Iridium (Ir), Zinc (Zn), Tin (Sn), Rhodium (Rh) and other metals. The bottom electrode 16 may be Platinum (Pt), Aluminum (Al), Ruthenium (Ru), Copper (Cu), Gold (Au) or any other metal or conductive substrate.

The base metal oxide layer 14 can be one or more of Praseodymium Calcium Manganese Oxide (PCMO), Lanthanum Calcium Manganese Oxide (LCMO), Lanthanum Strontium Nickel Oxide (LSNO), Nickel Oxide (NiₓO_{y}), Hafnium oxide (HfₓO_{y}), Aluminum oxide (AlₓO_{y}), Tantalum oxide (TaₓO_{y}) or any other metal oxide, metal nitride or metal oxynitride. The base metal oxide layer 14 may be a combination of more than one materials, phases or configurations of metal oxide. For example, the base metal oxide layer 14, itself, may be a layered material of one or more materials, phases, or configurations of metal oxides, metal nitride or metal oxynitride.

In some embodiments, the base metal oxide layer 14 can be a multi-layered structured that includes more than one material, phases or configurations of metal oxide. For example, base metal oxide layer 14 may be multi-layered comprising an amorphous layer of LCMO with a crystalline layer of LCMO. Other examples of multi-layered metal oxide layer 14 include a layer of PCMO with a layer of LCMO formed over the PCMO layer, or a layer of Aluminum oxide with a layer of Hafnium oxide formed over the Aluminum oxide layer and a layer of Tantalum oxide formed over the Hafnium oxide layer.

The base metal oxide layer 14 may be coupled to an optional barrier layer 20. The barrier layer 20 may include one or more wide band gap (or insulating) and oxygen ion or vacancy diffusion barrier materials such as Aluminum oxide (AlxOy), Hafnium oxide (HfxOy), Nickel oxide (NixOy), Tantalum oxide (TaxOy) or any other wide band gap material that has wider band gap than tone or both of the metal oxide layers and can serve as oxygen ion or vacancy diffusion barrier. In some embodiments, barrier layer 20 may itself be a layered material of one or more materials, phases, or configurations exhibiting a characteristic of wide band gap compared to the metal oxide layer 14. In other embodiments, barrier layer 20 may be of other low oxygen ion or vacancy diffusion barrier materials other than a metal oxide.

A top electrode layer 12 is coupled to base metal oxide layer 14 or the optional barrier layer 20. The top electrode 12 may be formed from a metal such as Platinum (Pt), Aluminum (Al), Ruthenium (Ru), Copper (Cu), Gold (Au), Tantalum (Ta), Titanium (Ti), Tungsten (W) or other.

FIG. 6B illustrates a particular structure for a memory device according to an embodiment of the present invention. As illustrated in FIG. 1B, a top metal oxide layer 18 is coupled to a base metal oxide layer 14. If a Gibbs free energy of oxidation of the top electrode 12 is less (more negative) than a Gibbs free energy for the formation (oxidation) of the base metal oxide layer 14, the top electrode metal 12 may form a top metal oxide 18 at the interface with the base metal oxide layer 14. If an optional barrier layer 20(not shown) is present between the top electrode metal 12 and the base metal oxide layer 14, then the top metal oxide 18 may form if the Gibbs free energy of oxidation of the top electrode 12 is less (more negative) than the Gibbs free energy of oxidation for the barrier layer.

In some embodiments, top metal oxide layer 18 may form as a result of heating. In other embodiments, top metal oxide 18 may be deposited rather than formed at the interface of barrier layer 20 and top electrode 12. The deposited top metal oxide layer may have a Gibbs free energy of oxidation more or less than a Gibbs free energy of oxidation for metal oxide layer 14. Also, the deposited top metal oxide layer may have a Gibbs free energy of oxidation more or less than a Gibbs free energy of oxidation for barrier layer 20.

In some embodiments, the base metal oxide layer 14 is thicker than top metal oxide layer 18. In an embodiment, the base metal oxide layer 14 is 10 to 100 times thicker than top metal oxide layer 18. For example, the thickness of top metal oxide layer 18 may be in the range of 10 to 100 angstroms and the thickness of metal oxide layer 14 may be between 100 to 10000 angstroms.

The barrier layer 20 is preferably thin and may be between 5 to 50 angstroms to allow for direct diffusion, passing, or tunneling of oxygen ions or vacancies from metal oxide layer 14 to top electrode metal 12. This direct diffusion/passing/tunneling of oxygen ions or vacancies may be spontaneous or may occur in response to an externally applied electrical or chemical potential. In a particular embodiment, barrier layer 20 is between 20 and 30 angstroms thick. Barrier layer 20 serves to slow down or stop the diffusion of oxygen ions or vacancies between metal oxide layer 14 and top electrode metal 12 or tope metal oxide layer 18, especially when externally applied potential is removed. Thus, barrier layer 20 may improve data retention of the memory device.

FIG. 6C shows several current-voltage (I-V) hysteresis curves for ionic type and vacancy type devices. As illustrated in curves 202a, 202b, and 202c, an ionic type device may yield a counter clock wise (CCW) hysteresis loop with positive bias at the top electrode. A vacancy type device may yield a clock wise (CW) hysteresis loop with positive bias at the top electrode as illustrated in curves 204a, 204b, and 204c. Furthermore, the hysteresis loop of the vacancy type device may be considerably larger than the hysteresis loop of ionic type devices. The CCW loop and CW loop may be swapped if the polarity of the bias is interchanged. These unique I-V characteristics can be utilized for various applications. Devices using such I-V characteristics include but are not limited to memory devices, current switches, diodes, etc.

The different hysteresis loops shown in FIG. 6C illustrate that for vacancy type devices, base metal oxide 14 (e.g., PCMO) and top metal oxide 18 may each function as a switchable resistor. Thus, a voltage with the correct polarity and amplitude can cause either resistor to switch from a low resistive state (LRS) to a high resistive state (HRS) or from a HRS to a LRS.

In a particular embodiment, the switch from LRS to HRS is used to ‘reset’ the memory device and the transition from HRS to LRS is used to ‘set’ the memory device. In some embodiments, the lower oxidation Gibbs free energy of the top electrode in a vacancy type device may result in a more stable top oxide layer structure which has a higher resistance in HRS than the resistance of PCMO in HRS. For example, the top metal oxide layer may be significantly thinner than PCMO and the resistance of the top metal oxide layer at LRS may be comparable to or lower than the resistance of PCMO at HRS. This feature may be utilized in the following way.

When a vacancy type device containing a top metal oxide layer is in the HRS; most of the voltage applied to the vacancy type device will drop across the top metal oxide and hence create a high internal field that causes the switching from the HRS to the LRS (‘set’). Many mechanisms for this switching are possible. For example, the internal field may push oxygen ions or vacancies through and out of the top metal oxide layer into the PCMO layer (i.e. base or bottom metal oxide layer), thus reducing the top metal oxide layer thickness. This movement of the oxygen ion or vacancy may be optionally through barrier layer 20.

On the other hand, when the vacancy type device is in the LRS, the voltage applied to the vacancy type device will be shared in the top metal oxide layer and in the PCMO layer or can be more in the PCMO layer. This allows field induced oxygen ion or vacancy migrations through and out of the PCMO layer into the top metal oxide layer and the top metal electrode layer. The influx of oxygen ions into the top metal oxide layer may cause further oxidation of the top metal electrode layer at the interface with the top metal oxide layer and may thus increase the thickness of the top metal oxide layer and cause the resistance of the device to switch from the LRS to the HRS (‘reset’). Again, this movement of the oxygen ion or vacancy out of the PCMO layer may optionally pass through barrier layer 20.

The relative layer thickness of the top metal oxide and the PCMO layers may be adjusted to secure desired levels of switching speed, switching potential, or both. These thickness adjustments may be produced by deposition condition changes and/or by depositing an initial top metal oxide layer before the deposition or the formation of top metal oxide layer 18.

FIG. 6D shows an exemplary asymmetric hysteresis loop behavior for a memory device of the current disclosure. Shown herein is a hysteresis loop formed as an electrical bias is applied across the memory device.

Referring now specifically to the right half of FIG. 6D, what is graphed is the current flow through the memory device as an electrical bias is ramped, for example, from 0V to 4V in 0.1V increments forming a first current-voltage (IV) curve 620. The first IV curve 620 is shown with the diamond symbols in the right half of the graph. This first IV curve 620 also demonstrates the current to voltage relationship of the device as it is switched from a “set” or low resistance state (LRS) to the “reset” or high resistance state (HRS). The maximum applied voltage, in this case 4V, is the reset voltage and the current readings in the first IV curve 620 are the sensing or read currents for the LRS set state in the positive bias direction.

After the first IV curve 620 is measured, the electrical bias can be ramped from 4V to 0V and measure a second IV curve 630. The second IV curve 630 is shown with the square symbols in the right half of the graph. Since the first IV curve 620 and the second IV curve 630 do not overlap they combine into a hysteresis loop. The current readings in the second IV curve 630 are the sensing or read currents for the HRS reset state in the positive bias direction.

The memory can be read or sensed at a positive voltage less than the reset voltage. For example, a possible reading or sensing voltage of 1V is shown by a vertical line on the graph. At 1V bias, this device has a read current for the LRS shown by the intersection of the first IV curve 620 and the vertical line at 1V to be ˜10⁻⁸ Amp. The read current for the HRS is shown by the intersection of the second IV curve then the “set” state as 630 and the vertical line at 1V to be ˜2×10⁻¹° Amp.

Referring now to the remaining left half of FIG. 6D, what is graphed is the current flow through the memory device as the electrical bias is ramped, for example, from 0V to −4V in 0.1V increments forming a third current-voltage (IV) curve 640. The third IV curve 640 is shown with the diamond symbols in the left half of the graph.

This third IV curve 640 also represents the current to voltage relationship of the device as it is switched from a “reset” or high resistance state (HRS) to a “set” or low resistance state (LRS). The maximum applied negative voltage, in this case −4V, is the set voltage and the current readings in the third IV curve 640 are the sensing or read currents for the HRS set state in the negative bias direction.

After the third IV curve 640 is measured, the electrical bias can be ramped from −4V to 0V to measure a fourth IV curve 650. The fourth IV curve 650 is shown with the square symbols in the right half of the graph. The current readings in the fourth IV curve 650 are the sensing or read currents for the LRS reset state in the positive bias direction.

Since the third IV curve 640 and the fourth IV curve 640 do not overlap they combine into a hysteresis loop. This hysteresis loop is different than the hysteresis loop formed by the first IV curve 620 and the second IV curve 630, thus the two hysteresis loops together form an asymmetric hysteresis loop or system.

The memory can be read or sensed at a negative voltage less than the set voltage. For example, a possible reading or sensing voltage of −1V is shown by a vertical line on the graph. At 1V bias, this device has a read current for the HRS shown by the intersection of the third IV curve 640 and the vertical line at −1V to be ˜10⁻¹⁰ Amp. The read current for the LRS is shown by the intersection of the fourth IV curve 650 and the vertical line at −1V to be ˜4×10⁻⁸ Amp.

Since the third IV curve 640 and the fourth IV curve 640 do not overlap they combine into a hysteresis loop. This hysteresis loop is different than the hysteresis loop formed by the first IV curve 620 and the second IV curve 630, thus the two hysteresis loops together form an asymmetric hysteresis loop or system.

The positive hysteresis loop and the negative hysteresis loop are asymmetric in size, shape and maximum current delivered. The asymmetry stems from heterojunction formed by the two metal oxide layers at their interface. The asymmetry of the hysteresis loops can be tuned for the desired resistance to voltage characteristics desired for the application. For example, the current level for one bias direction can be made switchable while holding the reversed bias current essentially un-switchable by compressing the hysteresis loop in one bias direction to remove the window. The tuning can be done by changing oxygen content of the top metal oxide and the base metal oxide as well as the Gibbs free energy difference between the two layers. For example, increasing the oxygen deficiency of the top metal oxide higher increases dominance of interface resistance to the bulk resistance.

The asymmetry of the hysteresis loop between the positive and negative bias can be a powerful tool in the operation of the memory device and be used in many ways. For example, since the read currents are different between negative bias read and positive bias read, the read bias can be store separately and be used as a key to unlock the data stored in a memory for a security application. The read bias bit map can be store physically or electronically separately.

As another example, the asymmetric hysteresis can be used as a back-up or repair mode for marginal memory devices. If the primary read bias does not produce good LRS to HRS current window, the other bias can be utilized. This repair mode can be implemented at a bit level, page level, sector level, or chip level.

In some embodiments of the memory device, a barrier layer may be introduced between the base metal oxide layer and the top metal oxide layer. FIG. 17 illustrates a memory device structure according to another embodiment of the present invention. As illustrated in FIG. 17, a barrier layer 20 is present between base metal oxide layer 14 and top metal oxide layer 18. Barrier layer 20 can improve the stability of a vacancy type device. During the RESET operation, the applied external potential may cause oxygen ions or vacancies to migrate through and out of base metal oxide layer 14 into top metal oxide layer 18, which may result in an increase in the thickness of top metal oxide layer 18 and causes a switch from the LRS to the HRS. The resulting HRS state concentrates oxygen ions, whether bonded to top metal oxide layer 18 or freely moving, in top metal oxide layer 18. This concentration of oxygen ions sets up a built-in field which can result in a drift current of oxygen ions out of top metal oxide layer 18. Diffusion forces also tend to move oxygen ions from high concentration regions such as top metal oxide layer 18 to low concentration regions such as base metal oxide layer 14. These drift and diffusion forces are generally weaker than the applied external potential but when the applied external potential is removed, the drift and diffusion forces can result in deterioration of the HRS by reducing the effective thickness of top metal oxide layer 18.

Although FIG. 17 shows barrier layer 20 functioning to reduce oxygen ion movement in one resistance state, it is to be noted that barrier layer 20 can also reduce oxygen ion or vacancy movement in other resistance states. For example, in the LRS, it may be possible for drift and diffusion forces to result in a net migration of oxygen ions from base metal oxide layer 14 to top metal oxide layer 18 after the applied ‘SET’ external potential is removed. This migration can also result in the deterioration of the LRS state by increasing the effective thickness of top metal oxide layer 18. For some devices, the oxygen ion movement may be better described as oxygen vacancy movement, and it is to be noted that barrier layer 20 can also be said to reduce oxygen vacancy movement for the devices.

The deterioration of the separate resistance states HRS and LRS, such as by diffusion of oxygen ions, can result in difficulty in distinguishing the two states. When the vacancy type devices are used, for example, as memory devices, such deterioration erodes the ability to distinguish between the two resistance states and consequently deteriorates data retention capability of the memory device. Therefore a solution to this problem would be advantageous, e.g., in the utility of the vacancy type devices of the present disclosure as memory devices.

Barrier layer 20 described above can serve as a solution to the aforementioned problem of data retention. A barrier layer of wide band gap or an oxygen ion diffusion barrier material may serve to impede the drift and diffusion of the oxygen ions into or out of the top metal oxide layer thus improving the stability of the individual RHS and LHS states. This improvement can thus result in improvement in data retention of digital data written into arrays of the vacancy type devices of the present disclosure as distinct RHS and LHS states.

The barrier layer can further serve as a means for adjusting vacancy type devices in order to secure desired levels of switching speed, switching potential, or both. This adjustment may be useful in, for example, preventing early switching from occurring during voltage ramp up. For example, for the oxygen ions to diffuse through the barrier layer, a minimum voltage may be needed, thus preventing early switching of resistance states during switching. This may improve resistance switching uniformity. Barrier layer 20 may thus improve the uniformity of an array of many devices to achieve a narrow switching distribution. Such narrower switching distribution may result in better overall performance of the memory system. In some embodiments, it would be easier to distinguish between the LRS and the HRS bits in the array, thus requiring less overhead such as error correction and allow for faster response time.

Further such improved control as provided by the narrower switching distribution can be used to allow for multiple digital data bits to be stored in a single device by allowing for multiple resistance stages to be distinguished in every cell in an array. For example, if the LRS allows for 1 micro amp (μA) of current to pass through the device at 1 Volt (V) of bias, and the HRS allows for 0.1 μA of current to pass through the device at 1 V of bias, then the window would be 1-0.1=0.9 μA. Then, if groups of devices, e.g., a sector of 1000 memory devices, were to be “read” and compared to a reference cell which allows 1 μA of current at 1 V of bias to determine the cells at LRS, the distribution of the currents for the 1000 memory devices influences whether it is easy to determine whether each device is in the LRS or the HRS. If the LRS currents are centered around 1 μA with an distribution of +/−0.5 μA (i.e. 0.5 μA to 1.5 μA) and the HRS currents are centered around 0.1 μA with a distribution of +/−0.5 μA (i.e., −0.4 μA to 0.6 μA), then the two distributions would overlap and there will be some devices for which it would be difficult to discern whether they are in the LRS or the HRS.

However, if the LRS currents are centered around 1 μA with a distribution of +/−0.1 μA (i.e. 0.9 μA to 1.1 μA) and the HRS currents are centered around 0.1 μA with a distribution of +/−0.1 μA (i.e. 0 μA to 0.3 μA), then the two distributions would be easily distinguishable and no devices would be in an ambiguous state. Further, additional states between the LRS and the HRS may be distinguishable. For example a middle resistance state (MRS) may be centered on 0.5 μA with a +/−0.1 μA distribution (i.e. 0.4 μA to 0.6 μA), and still be distinguishable from LRS and HRS devices as the distributions do not overlap. If 4 distinguishable states can be supported, then two bits of memory can be stored in a single device.

An embodiment of the present invention that includes a barrier layer provides a heterojunction memory device which can potentially retain data over a long period of time (e.g., 10+ years). The heterojunction memory device may be implemented in a variety of memory functions such as dynamic random access memory (DRAM), static random access memory (SRAM), one-time programmed memory (OTP), nonvolatile memory (NVM), embedded memory, cache memory, and others.

FIGS. 7A-7D illustrate steps in a process of fabricating a vacancy type heterojunction device according to an embodiment of the present invention. The vacancy type device so manufactured is capable of functioning as a memory device. As illustrated in FIG. 7A, a substrate 700 is provided. In some embodiments, substrate 700 may be a silicon substrate. It is to be noted that other types of substrates may also be used. A metal layer 702 is formed over an upper surface of substrate 700. In some embodiments, metal layer 702 may include one of Platinum (Pt), Aluminum (Al), Ruthenium (Ru), Copper (Cu), Gold (Au) or any other metal or conductive substrate. Metal layer 702 may be deposited using commonly known semiconductor fabrication techniques such as chemical vapor deposition (CVD) or physical vapor deposition (PVD), Sputtering, or the like. In some embodiments, metal layer 702 may be between 50 angstroms (Å) and 2000 Å in thickness. Thereafter a first metal oxide layer 704 may be deposited over the metal layer 702, as illustrated in FIG. 7B. In some embodiments, first metal oxide layer can include PCMO, LCMO, Tungsten Oxide, or Titanium Oxide and can be between 100 Å and 10000 Å in thickness. First metal oxide layer 704 can be deposited using any of the known semiconductor fabrication techniques described above.

Thereafter, a barrier layer 706 is formed over first metal oxide layer 704 as illustrated in FIG. 7C. Barrier layer 706 may be formed using a low oxygen ion or vacancy diffusion material and may be between 5 and 50 angstroms in thickness. In a particular embodiment, barrier layer 706 is between 10 and 30 angstroms thick. In one embodiment, an atomic layer deposition (ALD) process may be used to deposit barrier layer 706. In order to be an effective barrier, the non-uniformity of the barrier layer is preferred to be less than 5%. FIG. 7D illustrates the next step in forming the memory device. A second metal layer 708 is formed over barrier layer 706. Second metal layer 708 can be formed using one of physical vapor deposition techniques such as sputtering and evaporation, chemical vapor deposition techniques, and atomic layer deposition techniques and others. In some embodiments, the thickness of second metal layer 708 is between 30 Å and 10000 Å. As described above, if the Gibbs free oxidation energy of second metal layer 708 is lower than the Gibbs free energy of metal oxide layer 704, a second metal oxide layer 710 is spontaneously formed at the interface of second metal layer 708 and barrier layer 706. In some embodiments, the thickness of the second metal oxide layer can range between 100 Å and 1000 Å. The device structure illustrated in FIG. 7D can then be processed using known semiconductor fabrication techniques to create a functioning memory device.

It should be appreciated that the specific steps illustrated in FIGS. 7A-7D provide a particular method of fabricating a memory device according to an embodiment of the present invention. Other sequences of steps may also be performed according to alternative embodiments. For example, alternative embodiments of the present invention may perform the steps outlined above in a different order. Moreover, the individual steps illustrated in FIGS. 7A-7D may include multiple sub steps that may be performed in various sequences as appropriate to the individual step. Furthermore, additional steps may be added or removed depending on the particular applications. One of ordinary skill in the art would recognize many variations, modifications, and alternatives.

For example, FIG. 8 illustrates an alternative method for forming the memory device according to another embodiment of the present invention. As illustrated in FIG. 8, second metal oxide layer 710 is deposited over barrier layer 708 instead of it spontaneously forming as in FIG. 7D above. Thereafter, an inert metal layer 712 is provided on top of second metal oxide layer 710. In this instance, inert metal layer 712 forms a top electrode. Examples of inert metals that can be used for inert metal layer 712 include but are not limited to Platinum, Gold, and Silver. Through the use of the processes described above, a heterojunction oxide device with barrier layer can be provided that has memory characteristics that are significantly better than current art memory devices.

FIG. 9 illustrates an embodiment of the present invention as a switchable resistor 302 that has an idealized clockwise hysteresis of current versus voltage (I-V) 306 and a switchable resistor 304 that has an idealized counter clockwise I-V hysteresis 308. CW and CCW switching resistors 302 and 304 can be ionic or vacancy device shown in FIG. 1. They can also be constructed by using the same type device with top and bottom electrode reversed. Although the idealized I-V characteristics to used to illustrate an embodiment of a switching resistor device, it is clear to one of ordinary skill in the art that a real device will have I-V curve that differs from the ideal ones used here. However, the principle remains valid even.

FIG. 10 is a diagram of a back to back switching device 320′ according with an embodiment, as well as the I-V characteristics of such a combined device. These two resistors 302′ and 304′ have identical idealized I-V characteristics but with opposite polarities. The I-V characteristic is due to the fact that when one resistor is switching from HRS to LRS, the other resistor is switching from LRS to HRS. By using a switching voltage between the threshold voltages Va and Vb (with in positive side or negative side), both resistors 302′ and 304′ can be switched into LRS.

FIG. 11 shows that back-to-back switching device 320′ can give rise to a tri-state. When either resistor 302′ or 304′ is in HRS, the device 320′ is in HRS. So there are two HRS, the 01 or the 10 state. When both resistors are in LRS, the device is in LRS, or 00 state.

The table 406 in FIG. 12 illustrates a method for addressing the tri-states of the back to back switching device 320′ of FIG. 10. In general, 00 state can be set to 01 or 10 state and vice versa. FIG. 13 is a diagram illustrating a method to identify the 00 state 502 vs. 01, 10 state 504. Here the read voltage is within the two lower threshold voltage (Va−<V<Va+), therefore the device will remain in the original state. This is a nondestructive read.

The nondestructive read can only differentiate the 00 state (LRS) from either the 01 or 10 state (HRS state). To further differentiate 01 vs. 10 state, the polarity of the switching voltage (Vb−<V<Va− or Va+<V<Vb+) needs to be tested that cause the switching of HRS resistor to LRS. Since this is a destructive read, an additional pulse is needed to reset the device to the initial state before the destructive read. FIG. 14 is a diagram illustrating a method for identifying a 10 state vs. a 01 state. It is readily apparent to one of ordinary skill in the art that many other voltage pulses and sequences can be generated to read the tri-state.

The addressable and readable tri-state of a back-to-back switching resistor device can be used to create a memory array that avoid the need of an active transistor circuit to perform the select and set/reset and read. For example, since 01 and 10 states are two addressable and distinguishable HRS, they can be assigned to be the 0 or 1 state of a memory cell. Since both 0 and 1 state have high resistance, the system should have very low leakage current. A positive or negative voltage greater than Vb+ or smaller than Vb− can set the device to 1 or reset the device to 0 state as shown in the table for FIG. 12. For read operation, perform a test pulse to set the cell to 00 state and from the polarity of the bias to extract the 10 or 01 state. Note that the original state needs to be reinstalled after the read operation.

In order to address a particular memory cell, proper voltage on the read and write line are required so that the states of other cells in the memory array are not affected. FIG. 15 illustrates a diagram of biasing patterns that can fulfill this requirement when addressing single cell of an array in accordance with an embodiment.

The above discussions are base on two identical heterojunction oxide resistors. If the HRS states of the two switching resistors 702 and 704 have sizable differences as illustrated in FIG. 16, than it is possible to perform a nondestructive read of a back-to-back resistor device. By so doing, we can eliminate the need for resetting the device after the read.

Although the present disclosure has been described in accordance with the embodiments shown, one of ordinary skill in the art will readily recognize that there could be variations to the embodiments and those variations would be within the spirit and scope of the present disclosure. Accordingly, many modifications may be made by one of ordinary skill in the art without departing from the spirit and scope of the appended claims.

What is claimed is:

1. A memory device comprises:
a first metal layer;
a first metal oxide layer coupled to the first metal layer;
a second metal oxide layer coupled to the first metal oxide layer;
a second metal layer coupled to the second metal oxide layer;
wherein:
the first metal oxide layer is characterized by a first state having a first resistance and a second state having a second resistance;
the second metal oxide layer is characterized by a third state having a third resistance state and a fourth state having a fourth resistance; and
the first resistance is higher than the second resistance;
the third resistance is higher than the fourth resistance; and
the device has a property of forming an asymmetric hysteresis loop when a positive and a negative bias is applied across the device.

2. The device of claim 1, further comprising a barrier layer between the first metal oxide and the second metal oxide layers.

3. The device of claim 1, wherein an oxygen content of the second metal oxide is sub-stoichiometric

4. The device of claim 1, wherein an oxygen content of the second metal oxide layer is oxygen-deficient.

5. A method of forming a memory device comprising:
providing a substrate;
depositing a first metal layer;
selecting a first metal oxide layer coupled to the first metal layer;
selecting a second metal oxide layer coupled to the first metal oxide layer;
depositing a second metal layer coupled to the second metal oxide layer;
wherein:
the first metal oxide layer is characterized by a first state having a first resistance and a second state having a second resistance;
the second metal oxide layer is characterized by a third state having a third resistance state and a fourth state having a fourth resistance; and
the first resistance is higher than the second resistance;
the third resistance is higher than the fourth resistance; and
the device having a property of forming asymmetric hysteresis loop when a positive and a negative bias is applied across the device.

6. The device of claim 5, further comprising forming a barrier layer coupled to the first metal oxide and the second metal oxide layer is couple to the barrier layer.

7. The device of claim 5, wherein an oxygen content of the second metal oxide is sub-stoichiometric

8. The device of claim 5, wherein an oxygen content of the second metal oxide layer is oxygen-deficient.

9. A method of operating a memory device, comprising:
applying a first positive electrical bias to the device and measuring a first positive current;
applying a second positive electrical bias to the device and measuring a second positive current;
applying a first negative electrical bias to the device and measuring a first negative current;
applying a second negative electrical bias to the device and measuring a second negative current; and
selecting a sensing electrical bias for the device by comparing a difference between the first and second positive current, and a difference between the first and second negative current.

10. The method of claim 9, wherein the second positive electrical bias is lower than the first positive electrical bias to the device.

11. The method of claim 9, wherein the second negative electrical bias for sensing is lower than the first negative electrical bias to the device.
